(19) United States
(12) Patent Application Publication
(10) Pub. No.: US 2009/0058470 A1
(43) Pub. Date: Mar. 5, 2009

(54) SELF-STOP CIRCUIT USING NONVOLATILE STORAGE ELEMENT CHARGE AMOUNT AS TIMER

(75) Inventors: Takeshi Kawano, Osaka (JP); Shusaku Ota, Osaka (JP); Hiroshi Hoshika, Osaka (JP); Takeyasu Kuwata, Osaka (JP)

Correspondence Address: MCDERMOTT WILL & EMERY LLP, 600 13TH STREET, NW, WASHINGTON, DC, 20005-3096, US

(73) Assignee: MATSUSHITA ELECTRIC INUDSTRIAL CO., LTD., OSAKA (JP)

(21) Appl. No.: 12/280,592

(22) PCT Filed: Oct. 30, 2007
(86) PCT No.: PCT/JP2007/071111

§ 371 Date: Aug. 25, 2008

(30) Foreign Application Priority Data
Nov. 27, 2006 (JP) 2006-318227

(51) Int. Cl. G01R 19/165

(52) U.S. Cl. 327/58

(57) ABSTRACT

A self-stop circuit has a nonvolatile storage element (20), and a write terminal (50) and an erase circuit (30) for controlling the amount of electric charges charged in or discharged from the nonvolatile storage element (20). A determination circuit (40) determines that the amount of electric charges accumulated in the nonvolatile storage element (20) falls below a threshold, so as to detect an elapsed time. Thereby, the end of the lifespan of a product is detected and the operation of the product is stopped or modified after the end of the lifespan. When the operation is desired to be restored, electric charges are injected into the nonvolatile storage element (20) again, or a cancel signal is supplied through an external terminal (53) to the determination circuit (40).

### TECHNICAL FIELD

The present invention relates to a technique that causes a semiconductor chip to stop its operation by itself after the end of its product lifespan.

### BACKGROUND ART

Conventionally, there is a known self-destruction integrated circuit in which a fuse switch device is shut down by a voltage signal that is internally generated when predetermined conditions are satisfied, so that the circuit is perpetually destroyed or its function is perpetually stopped (see Patent Document 1).

Patent Document 1: Japanese Unexamined Patent Application Publication No. H07-297288

### DISCLOSURE OF THE INVENTION

### Problems to be Solved by the Invention

If a product continues to be used after the end of its product lifespan, there is an increasing risk of an erroneous operation or a functional failure that could jeopardize user's benefit or safety.

In the above-described self-destruction integrated circuit, after self-destruction or stop of a function has occurred, the operation of the circuit can never be restored. Therefore, it is not possible to determine whether the circuit has been stopped due to functional stop caused by a failure or due to self-destruction performed as a normal operation. Also, once functional stop has occurred, the operation of the circuit cannot be restored, so that it is disadvantageously difficult to analyze any failure.

An object of the present invention is to provide a semiconductor chip that stops its operation by itself after the end of its product lifespan.

Another object of the present invention is to achieve restoration of an operation after self-stop so as to secure ease of failure analysis.

### Solution to the Problems

The present invention employs a configuration of a self-stop circuit for stopping an operation of a semiconductor chip by itself after the end of its product lifespan, the circuit including a storage element in which an amount of electric charges accumulated in the storage element varies as time elapses, and a determination circuit for generating a stop signal so as to stop an original operation of a functional block on the semiconductor chip at a point in time when determining that the amount of electric charges in the storage element has changed to a predetermined amount.

The storage element can include an electric field effect transistor configured as a nonvolatile semiconductor storage element.

If an external output terminal for observing the stop signal is further provided, it is possible to easily confirm a self-stop state after the end of the product lifespan.

If an external input terminal for inputting a cancel for canceling the stop signal is further provided, an operation can be restored after self-stop.

If a storage element in which the amount of accumulated electric charges decreases as time elapses is employed, an erase circuit for generating an erase pulse train for discharging electric charges of the storage element is further provided so that the determination circuit generates the stop signal under conditions that the amount of electric charges in the storage element falls below a predetermined threshold. In this case, an operation can also be restored after self-stop by injecting electric charges via an external write terminal into the storage element again.

### EFFECT OF THE INVENTION

The present invention provides the above-described configuration that has the function of performing self-stop after the end of the lifespan of a product, and can restore an operation after self-stop. Therefore, the present invention can overcome a conventional problem that it cannot be determined whether a product has been accidentally destroyed due to any defect or has been stopped by itself after the end of the product lifespan.

Therefore, according to the present invention, a product that is beyond the end of its product lifespan or is out of order can be prevented from causing an erroneous operation or a functional failure that could jeopardize user's benefit or safety, and in addition, it is possible to easily analyze the product after being stopped, which is difficult in the conventional art.

### BRIEF DESCRIPTION OF THE DRAWINGS

FIG. 1 is a block diagram schematically showing a semiconductor chip on which a self-stop circuit according to an embodiment of the present invention is implemented.

FIG. 2 is a timing chart for describing an operation of the self-stop circuit of FIG.

FIG. 3 is a circuit diagram showing a detailed exemplary configuration of a nonvolatile storage element that can be used in the self-stop circuit of the present invention.

FIG. 4 is a diagram for describing an operation of the nonvolatile storage element of FIG. 3.

FIG. 5 is a block diagram schematically showing a semiconductor chip on which a self-stop circuit according to another embodiment of the present invention is implemented.

FIG. 6 is a block diagram schematically showing a semiconductor chip on which a self-stop circuit according to still another embodiment of the present invention is implemented.

### DESCRIPTION OF THE REFERENCE CHARACTERS

1 semiconductor chip
10 system circuit
20, 20a, 20b, 20c nonvolatile storage element
21, 21a, 21b, 21c voltage output signal
30 erase circuit
31 erase signal
40 determination circuit
41, 41a, 41b, 41c stop signal
50, 50a, 50b, 50c write terminal
51, 51a, 51b, 51c write signal
52 stop signal observation terminal
53 cancel signal input terminal
60, 60a, 60b, 60c functional block
70, 70a, 70b, 70c write terminal pad
71 stop signal observation pad
72 cancel signal input pad
200 electric field effect transistor
201, 201a, 201b, 201c erase signal input
202, 202a, 202b, 202c write signal input
203, 203a, 203b, 203c voltage output
221, 222, 231 to 233, 241 to 243 switch
250 sense amplifier
260 NOR circuit
261 NOR signal
800 electric charge injection instruction circuit
801 electric charge injection control circuit
802 write signal input
803 instruction signal
804 instruction signal input

### BEST MODE FOR CARRYING OUT THE INVENTION

Hereinafter, embodiments of the present invention will be described in detail with reference to the accompanying drawings.

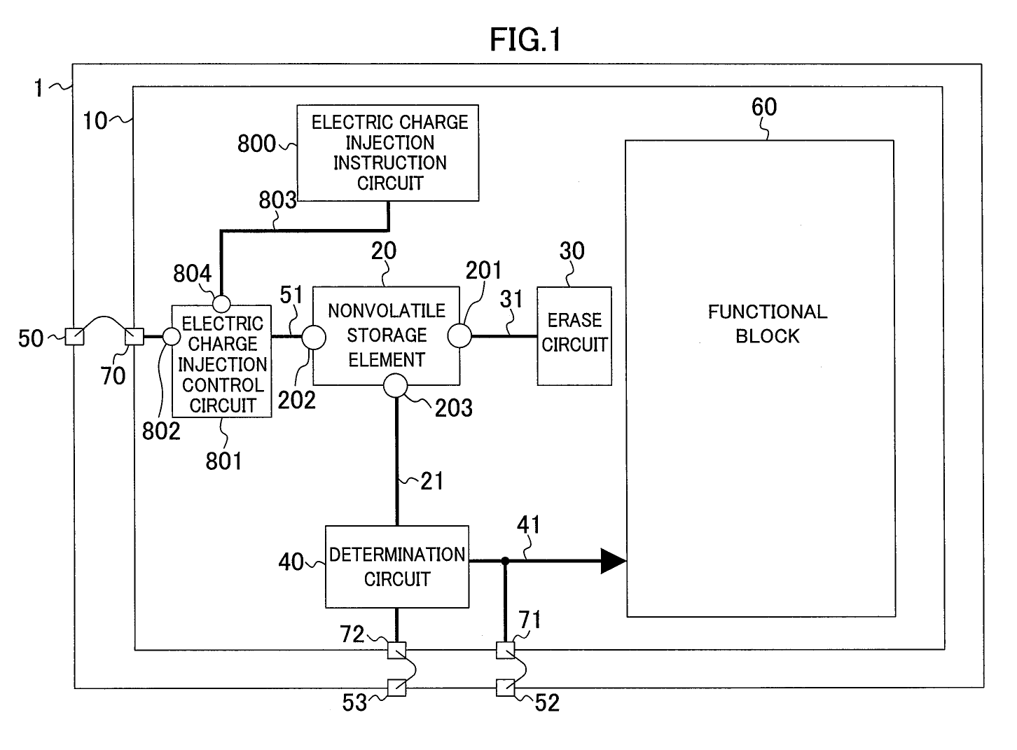

FIG. 1 is a block diagram schematically showing a semiconductor chip on which a self-stop circuit according to an embodiment of the present invention is implemented. A system circuit 10 included in the semiconductor chip 1 of this embodiment includes a nonvolatile storage element 20 for accumulating electric charges, a voltage output signal 21, an erase circuit 30, an erase signal 31, a determination circuit 40, a stop signal 41, a write signal 51, a functional block (controlled circuit) 60, a write terminal pad 70, a stop signal observation pad 71, a cancel signal input pad 72, an electric charge injection instruction circuit 800, an electric charge injection control circuit 801, and an instruction signal 803. The semiconductor chip 1 has a write terminal 50, a stop signal observation terminal 52, and a cancel signal input terminal 53. The write terminal 50 is connected to the write terminal pad 70, the stop signal observation terminal 52 is connected to the stop signal observation pad 71, and the cancel signal input terminal 53 is connected to the cancel signal input pad 72. All the connections are made by wire bonding.

The write terminal pad 70 is connected to a write signal input 802 of the electric charge injection control circuit 801. The electric charge injection instruction circuit 800 is connected via the instruction signal 803 to an instruction signal input 804 of the electric charge injection control circuit 801. The electric charge injection control circuit 801 is connected via the write signal 51 to a write signal input 202 of the nonvolatile storage element 20. The erase circuit 30 is connected via the erase signal 31 to an erase signal input 201 of the nonvolatile storage element 20. An output 203 of the nonvolatile storage element 20 is connected via the voltage output signal 21 to the determination circuit 40. An output of the determination circuit 40 is connected via the stop signal 41 to the functional block 60 and the stop signal observation pad 71. The cancel signal input pad 72 supplies an externally supplied cancel signal to the determination circuit 40.

Here, in this embodiment, it is assumed that if the write signal 51 is supplied to the nonvolatile storage element 20, the amount of electric charges accumulated in the nonvolatile storage element 20 increases so that the voltage of the output 203 increases. It is also assumed that if the erase signal 31 is supplied to the nonvolatile storage element 20, the voltage of the output 203 of the nonvolatile storage element 20 gradually decreases in proportion to a period of time in which the erase signal 31 is supplied. It is also assumed that if the voltage output signal 21 from the nonvolatile storage element 20 falls below a predetermined threshold, the determination circuit 40 outputs the stop signal 41.

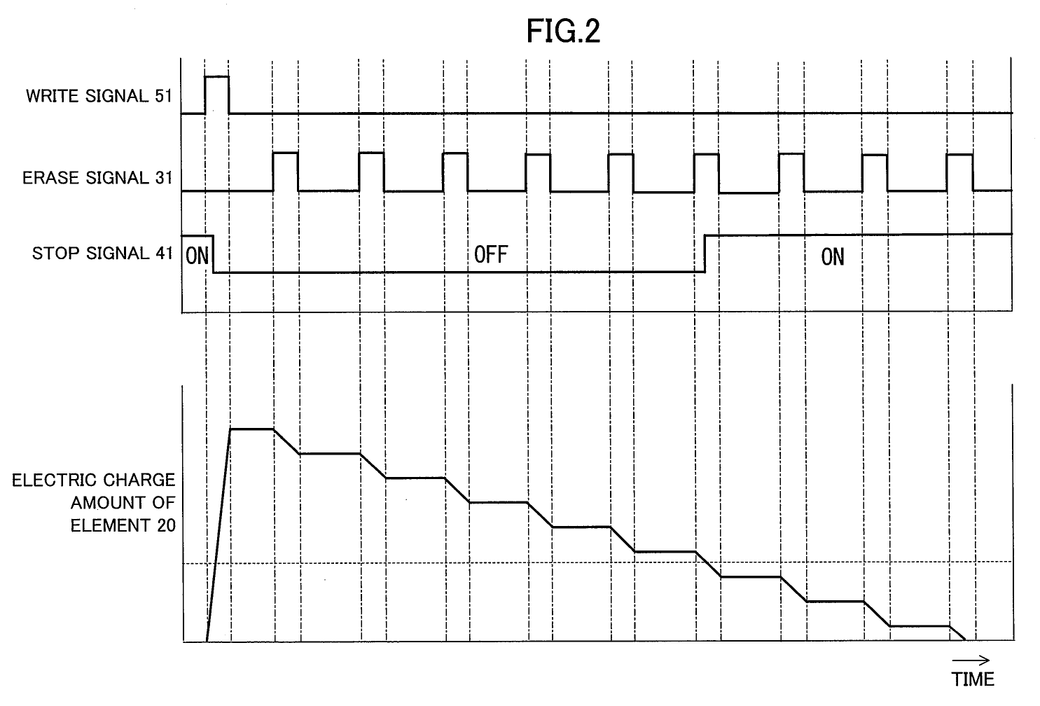

FIG. 2 is a timing chart for describing an operation of the self-stop circuit of FIG. 1. Initially, electric charges are injected through the write terminal 50 into the nonvolatile storage element 20. The voltage of the output 203 of the nonvolatile storage element 20 then increases, and the determination circuit 40 turns OFF the output of the stop signal 41, so that the stop of operation of the functional block 60 is canceled.

In this case, the instruction signal 803 indicating whether or not to permit electric charge injection through the write terminal 50 is input from the electric charge injection instruction circuit 800 to the electric charge injection control circuit 801. Therefore, when the instruction signal 803 indicating permission of writing is input from the electric charge injection instruction circuit 800 to the electric charge injection control circuit 801, electric charges are injected through the write terminal 50 into the nonvolatile storage element 20. By providing the electric charge injection instruction circuit 800 and the electric charge injection control circuit 801, the cancellation of the stop of operation of the functional block 60 due to erroneous writing through the write terminal 50 is disabled, so that it is possible to prevent the cancellation of the stop of operation that is not intended by the designer.

In the above-described state in which the stop of operation is canceled, if the erase circuit 30 continuously or intermittently outputs the erase signal 31, the voltage of the output 203 of the nonvolatile storage element 20 gradually decreases in proportion to a period of time in which the erase signal 31 is supplied. When the accumulation of the period of time in which the erase signal 31 is supplied exceeds a predetermined value, the voltage of the output 203 of the nonvolatile storage element 20 falls below a threshold of the determination circuit 40, so that the determination circuit 40 turns ON the stop signal 41 to stop the operation of the functional block 60.

Here, by appropriately the output interval of the adjusting erase signal 31, a period of time until the determination circuit 40 turns ON the stop signal 41 can be arbitrarily set, so that the operational lifespan of the product can be set.

By observing the stop signal 41 through the external terminal 52, it is possible to easily confirm that the functional block 60 is in the self-stop state due to the ON state of the stop signal 41. In addition, if the stop signal 41 is temporarily turned OFF by supplying a cancel signal via the external terminal 53 to the determination circuit 40, the operation can be restored after self-stop. The operation can also be restored after self-stop by injecting electric charges through the write terminal 50 into the nonvolatile storage element 20 again.

Although it is assumed in this embodiment that the amount of electric charges injected into nonvolatile storage element 20 is in proportion to the voltage of the output 203, the proportional relationship may not be exactly established. The intention of this embodiment is not impaired if a monotonic increase is secured. Also, although it is assumed that a voltage increases with an increase in the amount of electric charges, it may be assumed that the sign is reversed, i.e., a voltage increases with a decrease in the amount of electric charges.

Also, the write terminal 50 may not be provided on the semiconductor chip 1, and after an initial amount of electric charges is set in the nonvolatile storage element 20 during manufacture of the semiconductor chip 1, the write terminal pad 70 that is an internal terminal may be enclosed in a package so that electric charges cannot be injected again after assembly of the package. Thereby, the stop of operation of the functional block 60 is prevented from being canceled due to erroneous writing of the semiconductor chip 1 through an external terminal, so that the cancellation of the stop of operation that is not intended by the designer can be prevented. Also, since an external terminal for the write signal 51 can be removed, the number of external terminals on the semiconductor chip 1 can be reduced.

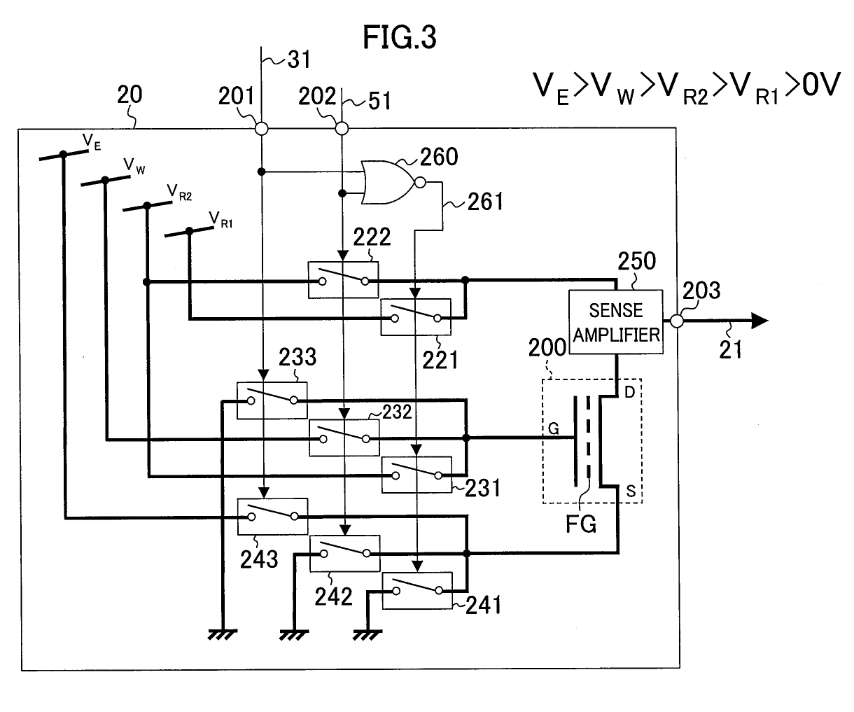

FIG. 3 shows a detailed exemplary configuration of the nonvolatile storage element 20 that can be used in the self-stop circuit of the present invention. The nonvolatile storage element 20 of FIG. 3 includes an electric field effect transistor 200 having a gate G, a source S, a drain D, and a floating gate FG, first to eighth switches 221, 222, 231 to 233, and 241 to 243, a sense amplifier 250, and a NOR circuit 260. The sense amplifier 250 generates the voltage output signal 21 corresponding to a current flowing between the source S and the drain D of the electric field effect transistor 200. The NOR circuit 260 generates a NOR signal 261 by a logical NOR operation of the erase signal 31 and the write signal 51. The first switch 221 connects the drain D of the electric field effect transistor 200 and a power supply V_{R1} in accordance with the NOR signal 261.

The second switch 222 connects the drain D of the electric field effect transistor 200 and a power supply V_{R2} in accordance with the write signal 51. The third switch 231 connects the gate G of the electric field effect transistor 200 and the power supply V_{R2} in accordance with the NOR signal 261. The fourth switch 232 connects the gate G of the electric field effect transistor 200 and a power supply V_{W} in accordance with the write signal 51. The fifth switch 233 connects the gate G of the electric field effect transistor 200 and 0 V in accordance with the erase signal 31. The sixth switch 241 connects the source S of the electric field effect transistor 200 and 0 V in accordance with the NOR signal 261. The seventh switch 242 connects the source S of the electric field effect transistor 200 and 0 V in accordance with the write signal 51. The eighth switch 243 connects the source S of the electric field effect transistor 200 and a power supply V_{E} in accordance with the erase signal 31. Here, V_{E}>V_{W}>V_{R2}>V_{R1}>0 V.

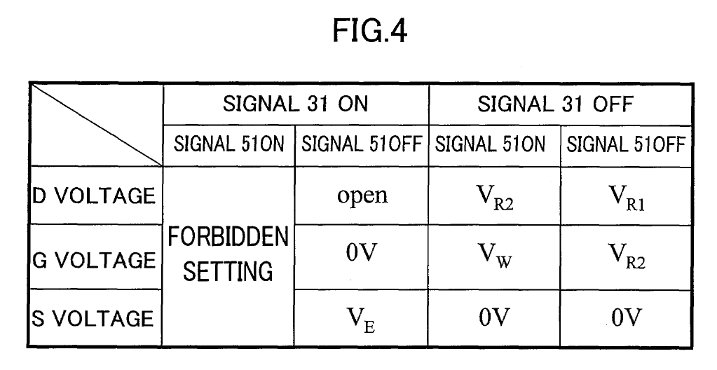

FIG. 4 is a diagram for describing an operation of the nonvolatile storage element 20 of FIG. 3. Here, the drain voltage, gate voltage, and source voltage of the electric field effect transistor 200 are referred to as “D voltage”, “G voltage”, and “S voltage”, respectively. Note that it is assumed that the erase signal 31 and the write signal 51 are forbidden to be simultaneously turned ON.

Firstly, when the erase signal 31 is OFF and the write signal 51 is ON, V_{R2} is supplied as the D voltage by the second switch 222, V_{W} is supplied as the G voltage by the fourth switch 232, and 0 V is supplied as the S voltage by the seventh switch 242, to the electric field effect transistor 200, so that electric charges are injected into the floating gate FG (write operation).

When the erase signal 31 is ON and the write signal 51 is OFF, 0 V is supplied as the G voltage by the fifth switch 233 and V_{E} is supplied as the S voltage by the eighth switch 243, to the electric field effect transistor 200, so that electric charges in the floating gate FG are released (erase operation).

When both the erase signal 31 and the write signal 51 are OFF, V_{R1} is supplied as the D voltage by the first switch 221, V_{R2} is supplied as the G voltage by the third switch 231, and 0 V is supplied as the S voltage by the sixth switch 241, to the electric field effect transistor 200, so that if a large amount of electric charges is accumulated in the floating gate FG, a current does not flow between the source S and the drain D, and if the amount of electric charges is small, a current flows. Thereby, the amount of electric charges accumulated in the floating gate FG can be determined based on the output of the sense amplifier 250 (read operation).

Note that the above-described floating gate FG may be any electric charge accumulation layer that achieves substantially the function of the present invention, and therefore, its implementation is not limited to the floating gate of a general electric field effect transistor.

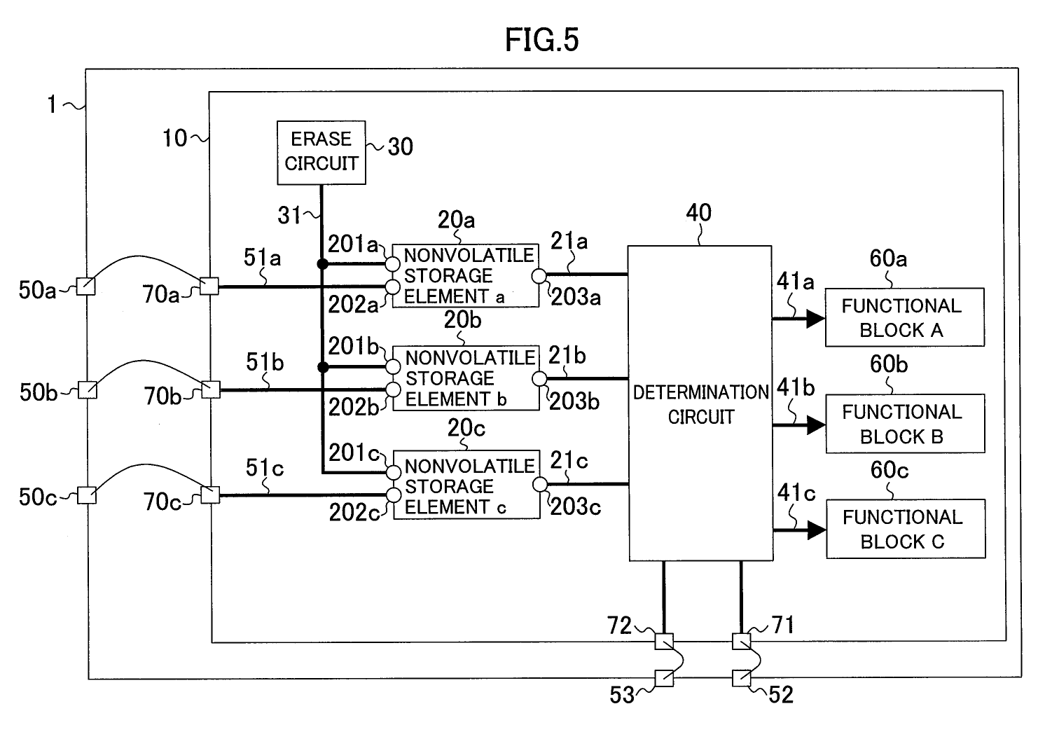

FIG. 5 is a block diagram schematically showing a semiconductor chip on which a self-stop circuit according to another embodiment of the present invention is implemented. The semiconductor chip 1 of this embodiment has first to third write terminals 50a, 50b and 50c, and includes first to third nonvolatile storage elements 20a, 20b and 20c, first to third stop signals 41a, 41b and 41c, and first to third functional blocks 60a, 60b and 60c in an internal system circuit 10. 70a, 70b and 70c indicate write terminal pads, 51a, 51b and 51c indicate write signals, 201a, 201b and 201c indicate erase signal inputs, 202a, 202b and 202c indicate write signal inputs, 203a, 203b and 203c indicate voltage outputs, and 21a, 21b and 21c indicate voltage output signals.

In this embodiment, the first nonvolatile storage element 20a can be allocated to the first functional block 60a, the second nonvolatile storage element 20b can be allocated to the second functional block 60b, and the third nonvolatile storage element 20c can be allocated to the third functional block 60c. In this case, the determination circuit 40 supplies first to third stop signals 41a, 41b and 41c that are independent from each other.

In order to improve the reliability of a determination result, the determination circuit 40 may simultaneously generate the first to third stop signals 41a, 41b and 41c at a point in time when determining that the amount of electric charges accumulated in each of the first to third nonvolatile storage elements 20a, 20b and 20c has been reduced to a predetermined amount. The determination may be performed based on the sum value of the amounts of electric charges accumulated in the first to third nonvolatile storage elements 20a, 20b and 20c.

Alternatively, the determination circuit 40 may simultaneously generate the first to third stop signals 41a, 41b and 41c based on the majority rule at a point in time when determining that the amounts of electric charges accumulated in two of the first to third nonvolatile storage elements 20a, 20b and 20c have been reduced to a predetermined amount, for example.

Alternatively, the determination circuit 40 may successively generate the first to third stop signals 41a, 41b and 41c so that the original operations of the first to third functional blocks 60a, 60b and 60c are each stopped in a stepwise manner in accordance with an output pattern of the first to third nonvolatile storage elements 20a, 20b and 20c.

Note that when a plurality of nonvolatile storage elements are used, the number of nonvolatile storage elements is not limited to three.

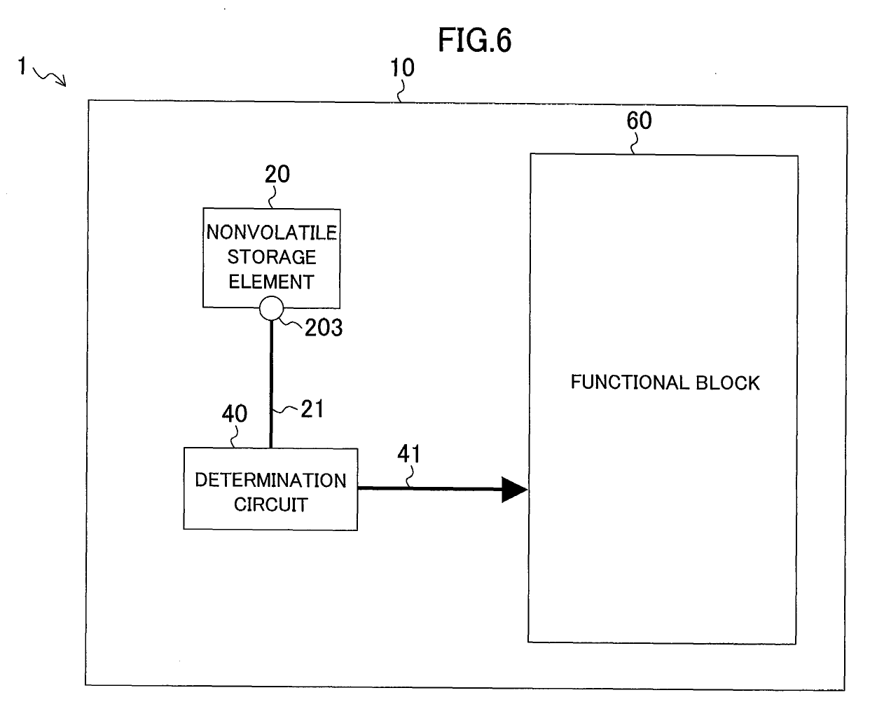

FIG. 6 is a block diagram schematically showing a semiconductor chip on which a self-stop integrated circuit according to still another embodiment of the present invention is implemented. In a system circuit 10 of this embodiment, the electric charge injection instruction circuit 800, the electric charge injection control circuit 801, and the erase circuit 30 of FIG. 1 are not provided.

According to this embodiment, an amount of electric charges with which the determination circuit 40 can turn OFF the stop signal 41 is previously injected into the nonvolatile storage element 20 by, for example, an electron beam means before manufacture or shipment of the semiconductor chip 1. If a sufficient time has passed since this initial state, the electric charges of the nonvolatile storage element 20 are gradually lost due to the tunnel effect, so that the voltage of the output 203 gradually decreases in proportion to time. Thereafter, if the accumulated time exceeds a predetermined value, the voltage of the output 203 of the nonvolatile storage element 20 falls below a threshold of the determination circuit 40, so that the determination circuit 40 turns ON the stop signal 41 to stop the operation of the functional block 60.

Since a decrease in the amount of electric charges in the nonvolatile storage element 20 due to the tunnel effect is typically small, a period of time until the stop signal 41 is turned ON can be set to be of the order of several years if the amount of electric charges injected into the nonvolatile storage element 20 and the threshold of the determination circuit 40 are appropriately set during manufacture or shipment. Therefore, if this embodiment is incorporated into a product, the lifespan of the product until the stop of operation can be set during manufacture.

### INDUSTRIAL APPLICABILITY

As described above, a product carrying the self-stop circuit of the present invention has a function of detecting its product lifespan and stopping its operation by itself, and is useful as an application for protecting user's safety from an unexpected operation that may occur due to a deterioration, a failure, or an erroneous operation that occurs after the end of the product lifespan.

The present invention is also applicable not only to an application for stopping an operation, but also to an application for limiting or modifying a function of a product before or after the end of the product lifespan, for example.

1. A self-stop circuit for detecting the end of a preset product lifespan of a semiconductor chip and stopping an original operation of a functional block on the semiconductor chip by itself, the circuit comprising:
a storage element including an electric field effect transistor configured as a nonvolatile semiconductor storage element for accumulating electric charges;
an erase circuit for generating an erase pulse train for discharging electric charges of the storage element so that the amount of electric charges in the storage element is reduced by a small amount in predetermined time intervals; and
a determination circuit for generating a stop signal so as to stop the original operation of the functional block under conditions that the amount of electric charges in the storage element falls below a predetermined threshold.

2. (canceled)

3. The self-stop circuit of claim 1, further comprising:
an external output terminal for observing the stop signal.

4. The self-stop circuit of claim 1, further comprising:
an external input terminal for inputting a cancel signal for canceling the stop signal so that the operation of the functional block can be restored even after generation of the stop signal.

5. (canceled)

6. (canceled)

7. The self-stop circuit of claim 1, further comprising:
an external input terminal for injecting electric charges into the storage element so that an initial amount of electric charges is set in the storage element or so that the operation of the functional block can be restored even after generation of the stop signal.

8. The self-stop circuit of claim 7, further comprising:
an internal circuit for permitting or forbidding injection of electric charges into the storage element.

9. The self-stop circuit of claim 1, further comprising:
an internal terminal for injecting electric charges into the storage element so as to set an initial amount of electric charges in the storage element during manufacture of the semiconductor chip, wherein the internal terminal is enclosed in a package so as to prevent electric charges from being injected into the storage element again after assembly of the package.

10. (canceled)

11. (canceled)

12. The self-stop circuit of claim 1, wherein
the determination circuit has a function of stopping an original operation of each of a plurality of functional blocks in a stepwise manner, depending on amounts of electronic charges in a plurality of storage elements in which the amounts of electronic charges accumulated in the plurality of storage elements each vary as time elapses.
